(19) United States
(12) Patent Application Publication
(10) Pub. No.: US 2024/0395482 A1
(43) Pub. Date: Nov. 28, 2024

(54) LUMINOUS KNOB SWITCH AND GRILL

(71) Applicant: NINGBO AGSUN PRODUCTS,INC., CIXI (CN)

(72) Inventors: Linqiang Wang, CIXI (CN); Bin Shen, CIXI (CN); Zecheng Han, CIXI (CN); Xuefei Mao, CIXI (CN); Xianghua Liu, CIXI (CN)

(21) Appl. No.: 18/793,639

(22) Filed: Aug. 2, 2024

(51) Int. Cl. H01H 19/02; H01H 19/04; H01H 19/14; H01H 36/00

(52) U.S. Cl. CPC H01H 19/025; H01H 19/04; H01H 19/14; H01H 36/0013; H01H 36/0033; H01H 2019/143

(57) ABSTRACT

The present invention discloses a luminous knob switch and a grill; a knob is rotated to make a relative rotation between a magnet and a magnetic force sensor to control an output signal of the magnetic force sensor to change and thus control operation of a functional member; the luminous knob switch further includes a power adapter to supply power to a functional assembly, and the grill with a luminous knob is powered by the adapter, which eliminates the need to consider battery life and avoids frequent battery replacement by customers.

### TECHNICAL FIELD

The present invention belongs to field of grill equipment, and specifically pertains to a luminous knob switch and a grill.

### BACKGROUND

A luminous knob is a member for improving the use atmosphere of grill equipment. However, knob lights used in gas grills on the market are all powered by batteries which generally have a short battery life of typically about 20 hours and can only exhibit one or two colors monotonously. Therefore, it is very important to obtain a luminous knob switch and a grill that overcome the above technical problems.

### SUMMARY

In order to solve at least one of the above technical problems, the present invention provides a luminous knob switch which includes a base and a knob rotatably mounted on the base; the luminous knob switch further includes a functional assembly which includes at least one functional member and a control circuit driving the functional member to operate, and the control circuit is provided with a magnetic force sensor thereon; the luminous knob switch further includes a magnet, the control circuit and the magnet are respectively arranged on the base and the knob, and the knob is rotated to make a relative rotation between the magnet and the magnetic force sensor to control an output signal of the magnetic force sensor to change and thus control operation of the functional member; and the luminous knob switch further includes a power adapter electrically connected to the functional assembly to supply power to the functional assembly.

With the technical solution described above, the present invention uses an adapter to supply power, which eliminates the need to consider battery life and avoids frequent battery replacement by customers. The power adapter described above provides 5V power in the present invention.

The control circuit further includes a first switch tube and a second switch tube, and when a magnetic field generated by the magnet is close to the magnetic force sensor, the first switch tube is turned on and the second switch tube is turned off; and when the magnetic field generated by the magnet is away from the magnetic force sensor, the first switch tube is turned off and the second switch tube is turned on.

The functional member includes at least one multi-color light assembly, an input end of the multi-color light assembly is connected to a second output end of the control circuit, and the multi-color light assembly includes at least two first light beads with different colors and a first chip controlling operation of the first light beads. A plurality of multi-color light assemblies are connected in parallel. The first chip can be programmed. That is, when the first chip receives a data signal of 24 bits with eight bits each corresponding to red, blue and green light, the first chip outputs the data signal to a next chip through a DOUT, and color and rhythm adjustment of each light board is achieved through software programming. That is, the first light beads are controlled by the first chip and can exhibit custom colors and different effects such as horse running and flowing water according to the program.

The functional member includes an indicator light assembly, an input end of the indicator light assembly is connected to a first output end of the control circuit, and the indicator light assembly includes at least one second light bead.

With the technical solution described above, the magnetic force sensor in the present invention forms a Hall switch to control colorful lights formed by the multi-color light assemblies and monochromatic lights formed by the indicator light assembly. The present invention makes it possible to distinguish whether a burner is turned on by two sets of lighting systems.

A light transmitting region is provided on a side wall of a peripheral side of the base or the knob for transmitting light of the multi-color light assembly and/or the indicator light assembly.

With the technical solution described above, side luminescence of the present invention can be realized.

The functional assembly includes a circuit board, the circuit board is mounted on the

base, and the base is provided with a perforation for a power cord of the power adapter to pass through.

The magnetic force sensor, the first chip and the second light bead of the present invention are fixed on a front face of the circuit board.

A first limiting protrusion is provided on an inner wall of the base, and a limiting groove matching the first limiting protrusion is provided on a peripheral side of the circuit board to prevent the circuit board from rotating circumferentially. At least one second limiting protrusion is provided on the inner wall of the base, and the second limiting protrusion is higher than or flush with a surface of the circuit board to limit a stroke of axial movement of the circuit board.

A grill includes a knob panel assembly. The knob panel assembly includes a panel and at least one luminous knob switch described above, the base is mounted on the panel, a circuit board is mounted on the base, and the functional assembly is placed on the circuit board. The panel is a burner panel.

Compared with the prior art, the present invention has the following advantages:
1. the present invention is simple in structure, a power adapter is used to supply power, which eliminates the need to consider battery life and avoids frequent battery replacement by customer;
2. Two built-in systems (the Hall switch and a magic light system) enable to distinguish whether the burner is turned on; and
3. The first light beads are controlled by the first chip and can exhibit custom colors and different effects such as horse running and flowing water according to the program.

### BRIEF DESCRIPTION OF THE DRAWINGS

FIG. 1 is a cross-sectional perspective view of the present invention;

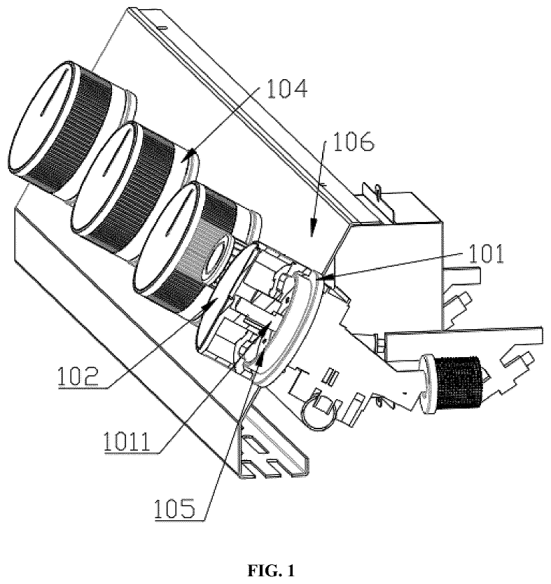

FIG. 2 is a schematic cross-sectional diagram of a knob according to the present invention;

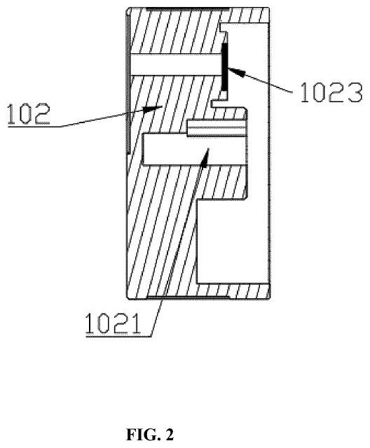

FIG. 3 is a structural schematic diagram of mounting a circuit board according to the present invention;

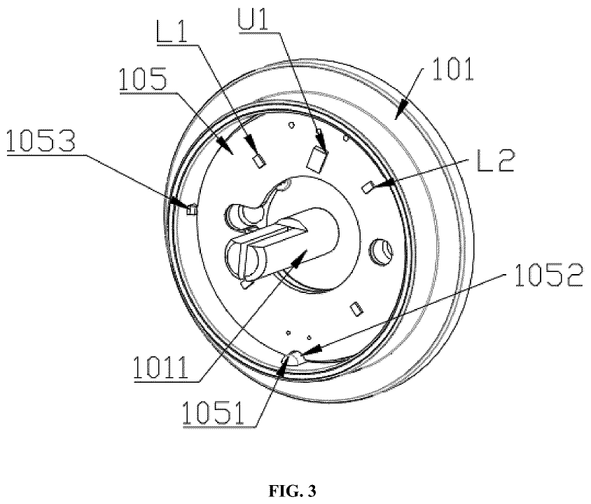

FIG. 4 is a structural schematic diagram of a base according to the present invention;

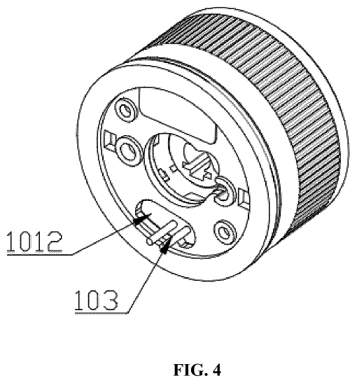

FIG. 5 is a circuit diagram of a control circuit according to the present invention;

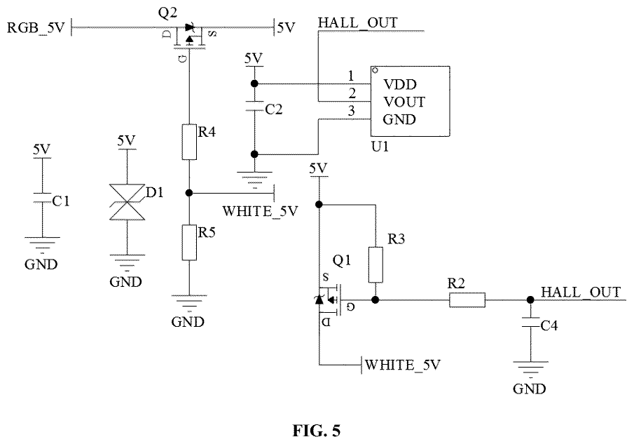

FIG. 6 is a circuit diagram of a multi-color light assembly according to the present invention;

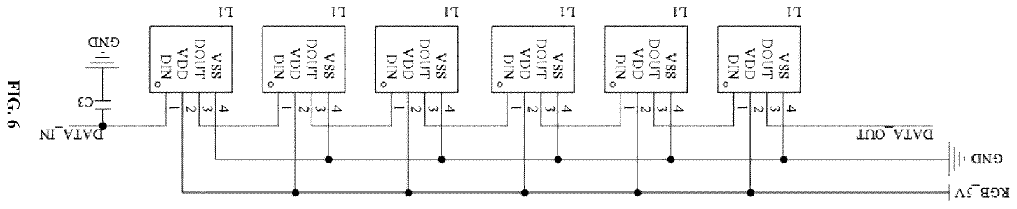

FIG. 7 is a circuit diagram of an indicator light assembly according to the present invention; and

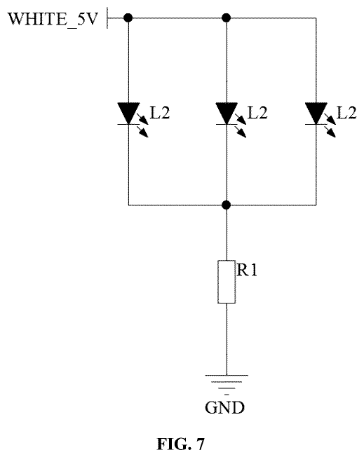

FIG. 8 is a circuit block diagram of the present invention.

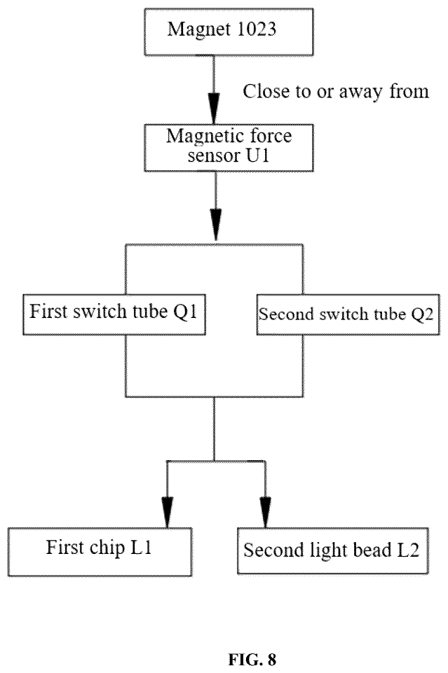

Reference numerals: 101 base; 1011 rotating shaft; 1012 perforation; 102 knob; 1021 rotating groove; 1023 magnet; 103 power adapter; 104 light transmitting region; 105 circuit board; 1051 first limiting protrusion; 1052 limiting groove; 1053 second limiting protrusion; 106 panel; Q1 first switch tube; Q2 second switch tube; L1 first chip; L2 second light bead; and U1 magnetic force sensor.

### DESCRIPTION OF THE EMBODIMENTS

In order to make those skilled in the art better understand the present invention and thereby define the scope of the present invention more clearly, the present invention is described below in detail with respect to some specific embodiments of the present invention. It should be noted that the following description only relates to some specific embodiments of the inventive concept and are only part of the embodiments of the present invention, specific and direct descriptions of relevant structures are merely for the convenience of understanding the present invention, and the specific features do not, of course, directly limit the implementation scope of the present invention.

With reference to the drawings, the present invention adopts the following technical solution: a luminous knob switch, includes a base 101, a functional assembly and a knob 102 rotatably mounted on the base 101; the functional assembly includes at least one functional member and a control circuit driving the functional member to operate, and the control circuit is provided with a magnetic force sensor U1 thereon; the luminous knob switch further includes a magnet 1023, the control circuit and the magnet 1023 are respectively arranged on the base 101 and the knob 102, and when the knob 102 is rotated, the magnet 1023 and the magnetic force sensor U1 are away from or close to each other to control an output signal of the magnetic force sensor U1 to change and thus to control operation of the functional member; and the luminous knob switch further includes a power adapter 103 electrically connected to the functional assembly to supply power to the functional assembly.

In the present embodiment, the magnet 1023 is fixed on the knob 102, and the functional assembly is placed on the base 101. In other embodiments, the functional assembly may be fixed on the knob 102, and the magnet 1023 may be fixed on the base 101.

With the technical solution described above, the present invention uses an adapter to supply power, which eliminates the need to consider battery life and avoids frequent battery replacement by customers. The power adapter 103 described above provides 5V power in the present invention.

The control circuit further includes a first switch tube Q1 and a second switch tube Q2, and when a magnetic field generated by the magnet 1023 is close to the magnetic force sensor U1, a HALL_OUT outputs a low level, so that the first switch tube Q1 is turned on, and a first output end of the control circuit outputs a high level signal, that is, a WHITE_5V outputs a high level, an indicator light assembly is on, the second switch tube Q2 is turned off, and colorful lights are off.

When the magnetic field generated by the magnet 1023 is away from the magnetic force sensor U1, the HALL_OUT outputs a high level, the first switch tube Q1 is turned off, the WHITE_5V outputs a low level, and the indicator light assembly is off; and the second switch tube Q2 is turned on, an RGB_5V outputs a high level, and the colorful lights are on.

The functional member includes at least one multi-color light assembly, an input end of the multi-color light assembly is connected to a second output end of the control circuit, and the multi-color light assembly includes at least two first light beads with different colors and at least two first chips L1 respectively controlling operation of each of the first light beads. The present invention adopts a first light bead structure with built-in first chips L1, which includes red, green and blue lights in the present embodiment. A plurality of multi-color light assemblies are connected in parallel. Each of the first chips L1 can be programmed. That is, when each of the first chips L1 receives a data signal of 24 bits with eight bits each corresponding to red, blue and green light, each of the first chips L1 outputs the data signal to a next chip through a DOUT, and color and rhythm adjustment of each light board is achieved through software programming. That is, each of the first light beads are controlled by at least two first chips L1 and can exhibit custom colors and different effects such as horse running and flowing water according to the program.

The functional member includes an indicator light assembly, an input end of the indicator light assembly is connected to the first output end of the control circuit, and the indicator light assembly includes at least one second light bead L2.

A white light may be selected as the indicator light assembly. That is, the indicator light assembly is in a normally white state when the knob 102 is not turned to turn on a burner.

With the technical solution described above, the magnetic force sensor U1 in the present invention forms a Hall switch to control colorful lights formed by the multi-color light assemblies and monochromatic lights formed by the indicator light assembly. The present invention makes it possible to distinguish whether the burner is turned on by two sets of lighting systems (with one using white lights and the other using colorful lights).

The magnetic force sensor U1, the first chips L1 and the second light bead L2 of the present invention are fixed on a front face of the circuit board.

A light transmitting region 104 is provided on a side wall of a peripheral side of the base 101 or the knob 102 for transmitting light of the multi-color light assembly and/or the indicator light assembly.

With the technical solution described above, side luminescence of the present invention can be realized. For example, the side wall on the peripheral side of the base 101 or the peripheral side of the knob 102 is made of a semi-permeable frosted material or a fully permeable material.

The functional assembly includes a circuit board 105, the circuit board 105 is mounted

on the base 101, and the base 101 is provided with a perforation 1012 for a power cord of the power adapter 103 to pass through.

A first limiting protrusion 1051 is provided on an inner wall of the base 101, and a limiting groove 1052 matching the first limiting protrusion 1051 is provided on a peripheral side of the circuit board 105 to prevent the circuit board 105 from rotating circumferentially. At least one second limiting protrusion 1053 is provided on the inner wall of the base 101, and the at least one second limiting protrusion 1053 is higher than or flush with a surface of the circuit board 105 to limit a stroke of axial movement of the circuit board 105.

Here, a rotating shaft 1011 is fixed on the base 101, a rotating groove 1021 matching the rotating shaft 1011 is provided on the knob 102, and the knob 102 is rotated to drive the magnet 1023 to rotate circumferentially to control the magnetic force sensor.

In another embodiment, there is described a knob panel assembly for use in a grill. The knob panel assembly includes a panel 106 and at least one luminous knob switch described above, a base 101 of the luminous knob switch is mounted on the panel 106, a circuit board 105 is mounted on the base 101 of the luminous knob switch, and a functional assembly of the luminous knob switch is provided on the circuit board 105. The panel 106 covers the burner in the grill.

Compared with the prior art, the present invention has the following advantages:
1. The present invention is simple in structure, and the power adapter 103 is used to supply power, which eliminates the need to consider battery life and avoids frequent battery replacement by customer.
2. Two built-in systems (the Hall switch and a magic light system) enable to distinguish whether the burner is turned on.
3. The first light beads are controlled by the first chips L1 and can exhibit custom colors and different effects such as horse running and flowing water according to the program.

What is claimed is:

1. A luminous knob switch, comprising:
a base;
a knob rotatably mounted on the base;
a functional assembly comprising at least one functional member and a control circuit driving the functional member to operate, the control circuit being provided with a magnetic force sensor thereon and further comprising a magnet further comprising a magnet, the control circuit and the magnet being respectively arranged on the base and the knob, and when the knob being rotated relative to the base, the magnet and the magnetic force sensor (U1) being away from or close to each other to control an output signal of the magnetic force sensor (U1) to change and thus to control operation of the at least one functional member; and
a power adapter electrically connected to the functional assembly to supply power to the functional assembly.

2. The luminous knob switch according to claim 1, wherein the control circuit further comprises a first switch tube (Q1) and a second switch tube (Q2), and when a magnetic field generated by the magnet is close to the magnetic force sensor, the magnetic force sensor (U1) outputs a low level, so that the first switch tube (Q1) is turned on, and a first output end of the control circuit outputs a high level signal; and when the magnetic field generated by the magnet is away from the magnetic force sensor (U1), the second switch tube (Q2) is turned off so that a second output end outputs a low level signal.

3. The luminous knob switch according to claim 2, wherein the at least one functional member comprises at least one multi-color light assembly, an input end of the multi-color light assembly is connected to the second output end of the control circuit, and the multi-color light assembly comprises at least two first light beads with different colors and at least two first chips (L1) controlling operation of each of the first light beads.

4. The luminous knob switch according to claim 3, wherein a plurality of multi-color light assemblies are connected in parallel.

5. The luminous knob switch according to claim 2, wherein the at least one functional member comprises an indicator light assembly, an input end of the indicator light assembly is connected to the first output end of the control circuit, and the indicator light assembly comprises at least one second light bead (L2).

6. The luminous knob switch according to claim 5, wherein a light transmitting region is provided on a side wall of a peripheral side of the base or the knob for transmitting light of the multi-color light assembly and/or the indicator light assembly.

7. The luminous knob switch according to claim 6, wherein the first light bead of the multi-color light assembly is fixed on the circuit board.

8. The luminous knob switch according to claim 6, wherein the second light bead (L2) is fixed on the circuit board.

9. The luminous knob switch according to claim 1, wherein the functional assembly comprises a circuit board, the circuit board is mounted on the base, and the base is provided with a perforation for a power cord of the power adapter to pass through.

10. The luminous knob switch according to claim 9, wherein a first limiting protrusion is provided on an inner wall of the base, and a limiting groove matching the first limiting protrusion is provided on a peripheral side of the circuit board to prevent the circuit board from rotating circumferentially.

11. The luminous knob switch according to claim 9, wherein at least one second limiting protrusion is provided on an inner wall of the base, and the second limiting protrusion is higher than or flush with a surface of the circuit board to limit a stroke of axial movement of the circuit board.

12. A grill, comprising a knob panel assembly, wherein the knob panel assembly comprises a panel and at least one luminous knob switch according to claim 1, a base of the at least one luminous knob switch is mounted on the panel, a circuit board is mounted on the base of the at least one luminous knob switch, and a functional assembly of the at least one luminous knob switch is provided on the circuit board.
